(19) United States
(12) Patent Application Publication
(10) Pub. No.: US 2015/0041180 A1
(43) Pub. Date: Feb. 12, 2015

(54) PRINTED CIRCUIT BOARD AND METHOD OF MANUFACTURING THE SAME

(71) Applicant: Samsung Electro-Mechanics Co., Ltd., Suwon (KR)

(72) Inventors: Young Jae LEE, Suwon (KR); Kyung Moo HAR, Suwon (KR); Young Do KWEON, Suwon (KR); Jin Gu KIM, Suwon (KR)

(73) Assignee: Samsung Electro-Mechanics Co., Ltd., Suwon (KR)

(21) Appl. No.: 14/104,611

(22) Filed: Dec. 12, 2013

(30) Foreign Application Priority Data
Aug. 8, 2013 (KR) 10-2013-0094190

(51) Int. Cl. H05K 1/02; H05K 3/46; H05K 3/18

(52) U.S. Cl. CPC H05K 1/02; H05K 3/182; H05K 3/4644
USPC 174/250; 29/846

(57) ABSTRACT

Disclosed herein are a printed circuit board including: an insulating layer; and a metal circuit layer formed on at least one surface of the insulating layer, wherein the metal circuit layer has surface roughness on only its one surface, and a method of manufacturing the same.

### CROSS REFERENCE(S) TO RELATED APPLICATIONS

This application claims the foreign priority benefit under 35 U.S.C. Section 119 of Korean Patent Application No. 10-2013-0094190, entitled “Printed Circuit Board and Method of Manufacturing the Same” filed on Aug. 8, 2013, which is hereby incorporated by reference in its entirety into this application.

### BACKGROUND OF THE INVENTION

1. Technical Field

The present invention relates to a printed circuit board and a method of manufacturing the same.

2. Description of the Related Art

In general, a printed circuit board (PCB) is used in industrial/consumer applications and the like. Such a printed circuit boards is a substrate made of a phenol resin, an epoxy resin and the like, on which circuit wiring is formed so as to mount a variety of components, and mechanically supports and electrically connects electronic components to supply power.

Recently, as electronic products becomes smaller, thinner, denser, packaged, lighter and simpler in order to improve portability, printed circuit boards have become multi-layered, micro-patterned, smaller and packaged to meet such demands.

Accordingly, printed circuit boards in which electronic components are embedded need to be highly dense and thin, and thus are changing from single-layer PCB to multi-layered PCBs. Further, components are also changing from a dual in-line package type (DIP) to a surface mount technology type (SMT), such that packaging density is ever-increasing.

In manufacturing printed circuit boards, since metal circuit layers and insulating layers made of polymer are alternately formed, it is important to strongly attach two different materials to each other.

To this end, previously, printed circuit boards undergo a preprocess in which surface roughness is formed on a metal circuit layer using an etching solution before an insulating layer is stacked, so as to increase adhesion between the metal circuit layer and the insulating layer.

However, when preprocessed to form surface roughness on a metal circuit layer using an etching solution, the width and thickness of the metal circuit layer are lost. Therefore, in forming micro metal circuit layers, a metal circuit layer may be lost or a desired electronic property may not be obtained.

Lately, in forming micro metal circuit layers, instead of the preprocessing using an etching solution to form surface roughness, there has been an attempt to improve materials of metal circuit layers or insulating materials. However, there is still a problem in that a plating solution permeates between a metal circuit layer and an insulating film where adhesion strength is weak in the final plating process to perform surface finish such as electroless nickel electroless palladium immersion gold (ENEPIG) method and the like.

### PRIOR ART DOCUMENT

### Patent Document

(Patent Document 1) Korean Patent Laid-open Publication No. 2006-0035162

### SUMMARY OF THE INVENTION

An object of the present invention is to provide a printed circuit board capable of preventing loss of metal circuit layers and a method of manufacturing the same.

According to an exemplary embodiment of the present invention, there is provided a printed circuit board including: an insulating layer; and a metal circuit layer formed on at least one surface of the insulating layer, wherein the metal circuit layer has surface roughness on only its one surface.

The metal circuit layers may have a width of 1 to 5 μm.

The surface roughness may have a dimension of 0.1 to 1 μm.

The printed circuit board may further include a surface finish layer formed on one surface of the metal circuit layers.

According to another exemplary embodiment of the present invention, there is provided a method of manufacturing a printed circuit board, including: forming a seed layer on at least one surface of a first insulating layer; forming a plating resist on the seed layer, the plating resist having an opening in which a first metal circuit layer is to be formed; forming the first metal circuit layer in the opening of the plating resist; forming surface roughness on only an exposed portion of the first metal circuit layer, leaving the plating resist unremoved; removing the plating resist; and removing the seed layer, leaving the portion where the first metal circuit layer is formed.

In the forming of the first metal circuit layer in the opening of the plating resist, the first metal circuit layer may have a width of 1 to 5 μm.

In the forming of the surface roughness on only an exposed portion of the first metal circuit layer, the surface roughness may have a dimension of 0.1 to 1 μm.

The method may further include, after the removing of the seed layer, forming, on at least one surface of the first insulating layer, a second insulating layer and a second metal circuit layer having surface roughness on only its one surface in this order; forming a solder resist such that a selected portion of the second metal circuit layer is exposed therethrough; and forming a surface finish layer on a surface of the second metal circuit layer.

In the forming of the second insulating layer and the second metal circuit, the second metal circuit layer may have a width of 1 to 5 μm and the surface roughness may have a dimension of 0.1 to 1 μm.

The forming of the surface finish layer on the surface of the second metal circuit layer may be performed by an electroless nickel immersion gold (ENIG) method or an electroless nickel electroless palladium immersion gold (ENEPIG) method.

### BRIEF DESCRIPTION OF THE DRAWINGS

FIGS. 1 and 2 are cross-sectional views of a printed circuit board according to an embodiment of the present invention; and

FIGS. 3 to 9 are cross-sectional views showing the manufacturing process of a printed circuit board according to an embodiment of the present invention.

### DESCRIPTION OF THE PREFERRED EMBODIMENTS

Hereinafter, exemplary embodiments of the present invention will be described with reference to the accompanying drawings. However, the exemplary embodiments are merely illustrative and the present invention is not limited thereto.

In describing the present invention, when a detailed description of well-known technology relating to the present invention may unnecessarily obscure the spirit of the present invention, a detailed description thereof will be omitted. Further, the following terminologies are defined in consideration of the functions in the present invention and may be construed in different ways depending on the intention of users and operators or conventions. Therefore, the definitions thereof should be construed based on the contents throughout the specification.

As a result, the spirit of the present invention is defined by the claims and the following exemplary embodiments may be provided to efficiently describe the spirit of the present invention to those skilled in the art.

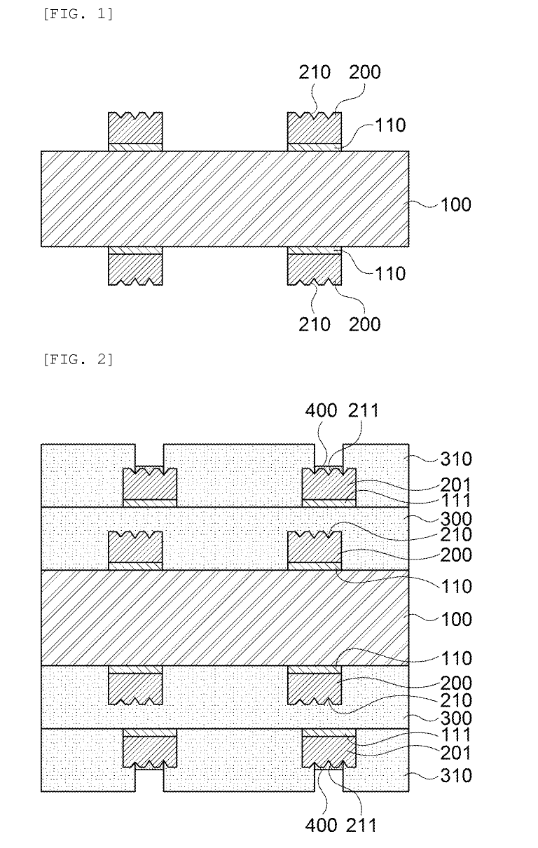

FIGS. 1 and 2 are cross-sectional views of a printed circuit board according to an embodiment of the present invention.

As shown in FIG. 1, the printed circuit board according to the embodiment of the present invention may be a single-layer printed circuit board. The printed circuit board includes a first insulating layer 100 and a first metal circuit layer 200 formed on at least one surface of the first insulating layer 100, the first metal circuit layer 200 having surface roughness on only one surface.

The first insulating layer 100 may be formed of an insulating material and may use an Ajinomoto build up film (ABF) to easily implement microcircuits or use prepreg to manufacture a thin printed circuit board. In addition, the first insulating layer 100 may be formed of an epoxy resin or a modified epoxy resin, a bisphenol A resin, an epoxy-novolak resin, or an aramid-reinforced, glass fiber-reinforced or paper-reinforced epoxy resin.

The first metal circuit layer 200 may be formed on at least one surface of the first insulating layer 100.

Here, the first metal circuit layer 200 may be formed of copper (Cu) which is a metal having electric conductivity or the like.

Here, the first metal circuit layer 200 may be formed on both surfaces of the first insulating layer 100 by performing a plating process on one surface of seed layers 110 each formed on both surfaces of the first insulating layer 100. However, the present invention is not limited thereto. The first metal circuit layer 200 may be formed only one of the surfaces of the first insulating layer 100.

In addition, the first metal circuit layer 200 may have the surface roughness 210 thereon.

Here, the surface roughness 210 may be formed on only one surface of the first metal circuit layer 200. By forming the surface roughness 210 on only one surface of the first metal circuit layer 200, loss of the metal circuit layer due to an undercut made under the first metal circuit layer 200 is minimized and electrical property is ensured.

Preferably, the first metal circuit layer 200 may have a width of 1 to 5 μm, and the surface roughness 210 may have a dimension of 0.1 to 1 μm. If the width of the first metal circuit layer 200 is below 1 μm, the first metal circuit layer 200 may be lost during etching to result in a defect. If the width of the first metal circuit layer 200 is above 5 μm, the loss of the first metal circuit layer 200 due to an undercut is not made during etching. Therefore, the first metal circuit layer 200 has a width of preferably 1 to 5 μm.

In accordance with the first metal circuit layer thus configured, the surface roughness 210 may have a dimension of preferably 0.1 to 1 μm, in order to prevent the loss of the first metal circuit layer 200 and, in a case of a multi-layered printed circuit board, to maximize adhesive strength between the first metal circuit layer 200 and a second insulating layer 300 which may be stacked on the first metal circuit layer 200.

As shown in FIG. 2, in a case of a multi-layered printed circuit board, the second insulating layer 300 and a second metal circuit layer 201 may be stacked on either surface of the first insulating layer 100 in this order.

Here, the second insulating layer 300 may be formed on either surface of the first insulating layer 100 so that it covers the first metal circuit layer 200. In particular, the second insulating layer 300 may be formed of resin material such as an Ajinomoto build-up film (ABF), prepreg (PPG) or polyimide, an epoxy, etc.

By forming the surface roughness 210 on only one surface of the first metal circuit layer 200, adhesive strength between the first metal circuit layer 200 and the second insulating layer 300 which may be stacked on the first metal circuit layer 200 is ensured, such that a printed circuit board having micro metal circuit layers with strong adhesion therebetween may be manufactured.

The second metal circuit layer 201 may be formed on one surface of the second insulating layer 300 through a plating process using a seed layer 111. The second metal circuit layer 201 may have the same dimensions with the first metal circuit layer 200, and, like the first metal circuit layer 200, may have surface roughness 211 on only one side.

In addition, a solder resist 310 may be formed on one surface of the second insulating layer 300 so that a selected part of the second metal circuit layer 201 is exposed therethrough. The solder resist 310 covers the remaining parts of the second metal circuit layer 201 except for the exposed portion so as to protect it from soldering or other external environment.

In addition, a surface finish layer 400 may be formed on one surface of the exposed part of the second metal circuit layer 201 through plating such as an Electroless Nickel Immersion Gold (ENIG) method or an Electroless Nickel Electroless Palladium Immersion Gold (ENEPIG) method.

By forming the surface roughness 211 on one surface of the second metal circuit layer 201, it is possible to prevent a plating solution from permeating between the second metal circuit layer 201 and the solder resist 310 when the surface finish layer 400 is formed. Therefore, it is possible to prevent insulating property from deteriorating due to the plating solution permeating between the second metal circuit layer 201 and the solder resist 310, thereby preventing a decrease in product reliability due to damage to the solder resist 310.

Hereinafter, a method of manufacturing a printed circuit board according to an exemplary embodiment of the present invention will be described in detail with reference to the accompanying drawings.

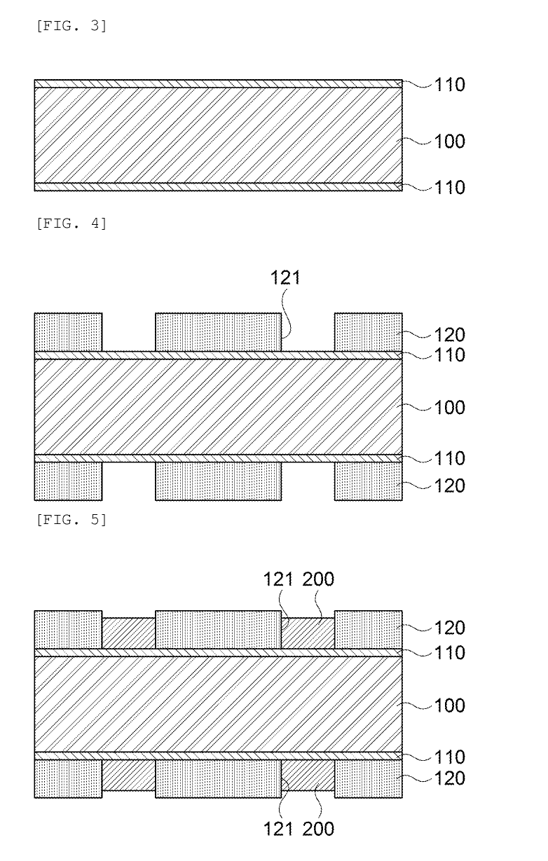

FIGS. 3 to 9 are cross-sectional views showing the manufacturing process of a printed circuit board according to an embodiment of the present invention.

Initially, as shown in FIG. 3, a seed layer 110 may be formed on one surface of a first insulating layer 100.

The first insulating layer 100 may use Ajinomoto build up film (ABF) to easily implement microcircuits or use prepreg to manufacture a thin printed circuit board. The first insulating layer 100 may be formed of an epoxy resin or a modified epoxy resin, a bisphenol A resin, an epoxy-novolak resin, or an aramid-reinforced, glass fiber-reinforced or paper-reinforced epoxy resin.

The seed layer 110 formed on one surface of the first insulating layer 100 serves as a lead-in line of a first metal circuit layer 200 to be described below, and is typically formed through an electroless copper plating process, sputtering or the like.

Then, as shown in FIG. 4, a plating resist 120 having an opening 121, in which the first metal circuit layer 200 is to be formed, may be formed on the seed layer 110.

The plating resist 120 is provided for selectively forming the first metal circuit layer 200 later to form the first metal circuit layer 200.

That is, the first metal circuit layer 200 is not formed on the portion covered by the plating resist 120 and is formed in the opening 121 only.

In order to form the plating resist 120 having the opening 121, an exposure process in which a photosensitive ink or a dry film is formed on one surface of the seed layer 110 and selectively curing it by illuminating light thereon through a mask which is patterned to correspond to the first metal circuit layer 200, and a development process (photolithography process) in which uncured portions are removed may be performed.

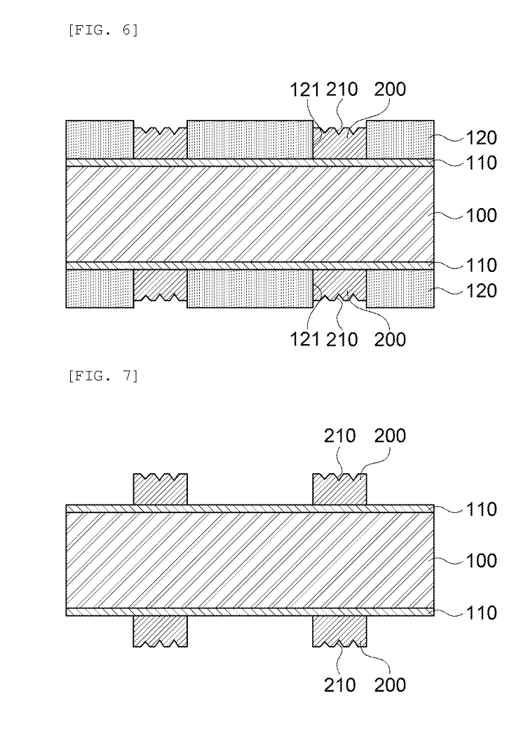

Then, as shown in FIG. 5, the first metal circuit layer 120 may be formed in the opening 121 of the plating resist 120.

Here, the first metal circuit layer 200 may be formed using the seed layer 110 as a lead-in line through an electroplating process and may be formed by filling the opening 121 of the plating resist 120. Preferably, the first metal circuit layer 200 is lower than the plating resist 120 in order to form surface roughness 210 to be formed through etching.

Subsequently, as shown in FIG. 6, leaving the plating resist 120 as it is, the surface roughness 210 may be formed on only one surface of the exposed portion of the first metal circuit layer 200.

The surface roughness 210 is formed by etching the exposed portion of the first metal circuit layer 200 through the opening 121 of the plating resist 120, to have a bumpy surface.

Preferably, the first metal circuit layer 200 may have a width of 1 to 5 μm, and the surface roughness 210 may have a dimension of 0.1 to 1 μm. If the width of the first metal circuit layer 200 is below 1 μm, the first metal circuit layer 200 may be lost during etching to thereby result in a defect. If the width of the first metal circuit layer 200 is above 5 μm, the loss of the metal circuit layer 200 due to an undercut is not made during etching. Therefore, the first metal circuit layer 200 has a width of preferably 1 to 5 μm. In accordance with the first metal circuit layer thus configured, the surface roughness 210 may have a dimension of preferably 0.1 to 1 μm, in order to prevent the loss of the first metal circuit layer 200 and to maximize adhesive strength between the first metal circuit layer 200 and a second insulating layer 300 to be described below.

Subsequently, as shown in FIG. 7, the plating resist 120 may be removed.

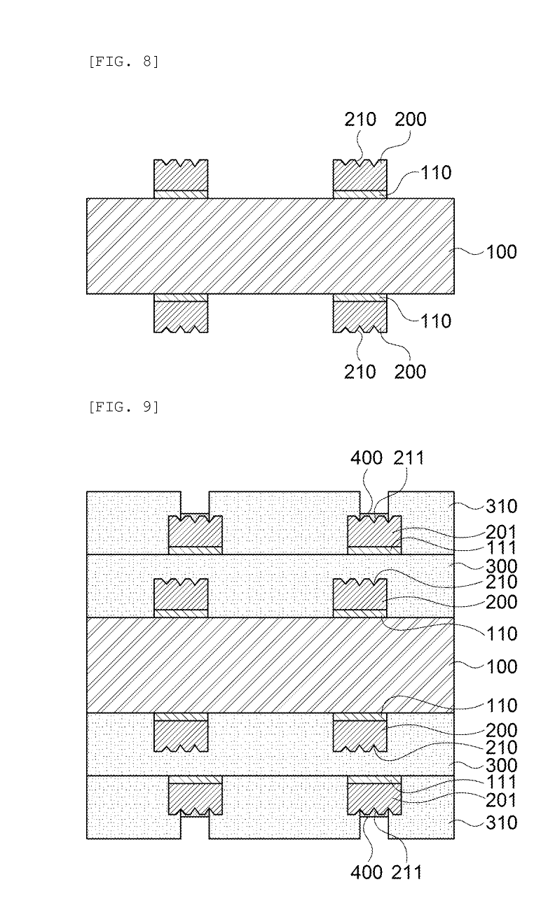

Thereafter, as shown in FIG. 8, the seed layer 110 may be removed leaving the portion on which the first metal circuit layer 200 is formed.

The seed layer 110 covered by the plating resist 120 is exposed to the outside as a result of the previous removal of the plating resist 120. By removing the portion of the seed layer 110 on which the first metal circuit layer 200 is not formed through wet etching such as flash etching, the first metal circuit layers 200 formed through the plating process are electrically separated from one another so as to function independently.

Then, as shown in FIG. 9, a second insulating layer 300 and a second metal circuit layer 201 having surface roughness 211 on only one surface may be stacked on at least one surface of the first insulating layer 100 in this order.

Since the surface roughness 210 is formed on only one surface of the first metal circuit layer 200 when the second insulating layer 300 is formed, adhesive strength between the first metal circuit layer 200 and the second insulating layer 300 may be ensured, such that a printed circuit board having micro metal circuit layers with strong adhesion therebetween may be manufactured.

In addition, a seed layer 111 is formed on one surface of the second insulating layer 300 using a method such as sputtering or electroless plating, and the second metal circuit layer 201 having the surface roughness 211 on only one surface through the same process as the first metal circuit layer 200.

Then, a solder resist layer 310 may be formed such that a selected portion of the second metal circuit layer 201 is exposed. The solder resist 310 covers the remaining parts of the second metal circuit layer 201 so as to protect it from soldering or other external environment.

Then, a surface finish layer 400 may be formed on the surface of the second metal circuit layer 201.

Here, a surface finish layer 400 may be formed on the surface of the exposed part of the second metal circuit layer 201, on which the solder resist 310 is not formed, through plating such as an Electroless Nickel Immersion Gold (ENIG) method or an Electroless Nickel Electroless Palladium Immersion Gold (ENEPIG) method.

Since the surface roughness 211 is formed on the surface of the second metal circuit layer 201, it is possible to prevent a plating solution for forming the surface finish layer 400 from permeating between the second metal circuit layer 201 and the solder resist 310.

That is, it is possible to prevent insulating property from deteriorating due to the plating solution permeating between the second metal circuit layer 201 and the solder resist 310, thereby preventing decrease in product reliability due to damage to the solder resist 310.

As set forth above, according to the embodiments of the present invention, by forming surface roughness on only one surface of a metal circuit layer, it is possible to prevent an undercut is made in the metal circuit layer, such that loss of the metal circuit layer can be minimized, electrical property can be ensured. Further, adhesive strength between the metal circuit layer and an insulating layer can be ensured such that a printed circuit board having micro metal circuit layers with strong adhesion therebetween can be manufactured.

Further, it is possible to prevent a plating solution from permeating between a metal circuit layer and a solder resist while performing surface finish on the metal circuit layer.

Although the exemplary embodiments of the present invention have been disclosed for illustrative purposes, those skilled in the art would appreciate that various modifications, additions and substitutions are possible, without departing from the scope and spirit of the invention as disclosed in the accompanying claims.

Accordingly, the scope of the present invention is not construed as being limited to the described embodiments but is defined by the appended claims as well as equivalents thereto.

What is claimed is:

1. A printed circuit board, comprising:
an insulating layer; and
metal circuit layers formed on at least one surface of the insulating layer,
wherein each of the metal circuit layers has surface roughness on only one surface.

2. The printed circuit board according to claim 1, wherein the metal circuit layers have a width of 1 to 5 μm.

3. The printed circuit board according to claim 1, wherein the surface roughness has a dimension of 0.1 to 1 μm.

4. The printed circuit board according to claim 1, further comprising a surface finish layer formed on one surface of the outermost metal circuit layer among the metal circuit layers.

5. A method of manufacturing a printed circuit board, comprising:
forming a seed layer on at least one surface of a first insulating layer;
forming a plating resist on the seed layer, the plating resist having an opening in which a first metal circuit layer is to be formed;
forming the first metal circuit layer in the opening of the plating resist;
forming surface roughness on only an exposed portion of the first metal circuit layer, leaving the plating resist unremoved;
removing the plating resist; and
removing the seed layer, leaving the portion where the first metal circuit layer is formed.

6. The method according to claim 5, wherein, in the forming of the first metal circuit layer in the opening of the plating resist, the first metal circuit layer has a width of 1 to 5 μm.

7. The method according to claim 5, wherein, in the forming of the surface roughness on only an exposed portion of the first metal circuit layer, the surface roughness has a dimension of 0.1 to 1 μm.

8. The method according to claim 5, further comprising:
after the removing of the seed layer, forming, on at least one surface of the first insulating layer, a second insulating layer and a second metal circuit layer having surface roughness on only its one surface in this order;
forming a solder resist such that a selected portion of the second metal circuit layer is exposed therethrough; and
forming a surface finish layer on a surface of the second metal circuit layer.

9. The method according to claim 8, wherein, in the forming of the second insulating layer and the second metal circuit, the second metal circuit layer has a width of 1 to 5 μm and the surface roughness has a dimension of 0.1 to 1 μm.

10. The method according to claim 8, wherein the forming of the surface finish layer on the surface of the second metal circuit layer is performed by an electroless nickel immersion gold (ENIG) method or an electroless nickel electroless palladium immersion gold (ENEPIG) method.
